(19) United States
(12) Patent Application Publication
(10) Pub. No.: US 2026/0074103 A1
(43) Pub. Date: Mar. 12, 2026

(54) Energy Processing for Magnetic Coil Demagnetization

(71) Applicant: Siemens Healthcare Limited, Camberley (GB)

(72) Inventors: Lei Xu, Shenzhen (CN); Le Jiang, Shenzhen (CN); Hai Ning Yang, Shenzhen (CN); Jun Zhao Wu, Shenzen (CN)

(73) Assignee: Siemens Healthcare Limited, Camberley (GB)

(21) Appl. No.: 19/324,352

(22) Filed: Sep. 10, 2025

(30) Foreign Application Priority Data
Sep. 10, 2024 (CN) 202411266685.4

(51) Int. Cl. H01F 13/00; G01R 33/3815; H01F 6/00; H01F 6/04; H01F 6/06

(52) U.S. Cl. CPC H01F 13/006; G01R 33/3815; H01F 6/003; H01F 6/008; H01F 6/04; H01F 6/06

(57) ABSTRACT

An energy processing system and method for a magnetic coil, a coil unit, a superconducting magnet, and a magnetic resonance imaging system are disclosed. The system includes an energy conversion system configured to regulate voltage or current of coil energy during demagnetization, receive the coil's energy nonlinearly by collecting with a low voltage first followed by a high voltage, and output electric energy with a stable voltage or current adapted to an energy storage system. The energy storage system is configured to accumulate and store the converted energy. An energy release system is configured to release electricity stored in the energy storage system. A control system is configured to control the energy conversion system to perform energy conversion during coil demagnetization, and to monitor the energy storage system and the energy release system to implement charging and discharging control.

### TECHNICAL FIELD

The present disclosure relates to the technical field of Magnetic Resonance (MR) imaging, and in particular, to an energy processing system and method for a magnetic coil, a coil unit, a superconducting magnet, and a magnetic resonance imaging system.

### BACKGROUND

A Magnetic Resonance Imaging (MRI) system is based on a magnetic field generated by a magnet and uses the nuclear magnetic resonance phenomenon to obtain information on the molecular structure and internal structure of a human body, etc.

A coil unit of a superconducting magnet is a key functional component in the MRI system, and is used for forming a main magnetic field required for detection. During use, it undergoes the processes of excitation and demagnetization. The excitation process primarily uses a power supply to provide energy, and the demagnetization process primarily involves converting electric energy into heat through a plurality of diodes, and then using a cooling system to dissipate the heat.

Some MRI systems utilize large aluminum blocks for heat dissipation. However, considering the low heat capacity of metal, the large amount of energy in the coil, and the temperature limits of the system components, the metal cooling block needs to have sufficient weight, which makes the metal cooling block larger in size, occupying valuable space in the magnetic resonance imaging system, and thereby making the system bulky. Some other MRI systems have an internal Run Down Load (RDL) component, which uses an air-cooled heat sink such as a finned fan, and/or a water-cooled heat sink. However, this heat dissipation manner is costly and requires an additional power or water supply, thereby increasing system complexity.

Therefore, those skilled in the art are still striving to find other solutions for energy conversion in superconducting magnetic coil units.

### SUMMARY

In view of this, the aspects of the present application provide an energy processing system and method for a magnetic coil, a coil unit, a superconducting magnet, and a magnetic resonance imaging system, so as to reduce heat dissipation costs and improve energy utilization.

An energy processing system for a magnetic coil proposed in the aspects of the present application comprises: an energy conversion system configured to: perform voltage or current regulation on electric energy of the magnetic coil during demagnetization of the magnetic coil, receive the energy of the magnetic coil in a nonlinear manner by collecting the energy of the magnetic coil with a low voltage first followed by a high voltage, and output electric energy with a stable voltage or a stable current that is adapted to an energy storage system; the energy storage system configured to accumulate and store the electric energy output by the energy conversion system; an energy release system configured to release electricity stored in the energy storage system; and a control system configured to control the energy conversion system to perform energy conversion during the demagnetization of the magnetic coil; further configured to: monitor the energy storage system, and when an amount of electricity stored in the energy storage system does not reach a set threshold, control the energy storage system to accumulate and store the electric energy output by the energy conversion system, and when the amount of electricity stored in the energy storage system reaches the set threshold or when a discharge instruction is received, control the energy release system to release the electricity stored in the energy storage system; and further configured to adjust discharge power of the energy release system according to a load condition; wherein nonlinear control of demagnetization speed is implemented by controlling a voltage at which the energy conversion system collects the energy of the magnetic coil and controlling the discharge power of the energy release system.

In an implementation, the control system comprises: an energy conversion control circuit configured to control the energy conversion system to turn on or off an electrical connection with the magnetic coil, and being able to control the energy conversion system to convert the energy of the magnetic coil in a nonlinear manner by collecting the energy of the magnetic coil with a low voltage first followed by a high voltage; a charging control circuit configured to control the energy storage system to turn on a charging channel with the energy conversion system or turn on a discharge channel with the energy release system; a load discharge control circuit configured to control a voltage or current of the energy release system; and a main controller configured to: during the demagnetization of the magnetic coil, send, to the energy conversion control circuit, a first control signal indicating that an electrical connection between the energy conversion system and the magnetic coil is turned on according to a required collection voltage, and simultaneously send, to the charging control circuit, a second control signal indicating that the charging channel between the energy storage system and the energy conversion system is turned on; and when it is monitored that the amount of electricity stored in the energy storage system reaches the set threshold or when the discharge instruction is received, send, to the charging control circuit, a third control signal indicating that the energy storage system turns on the discharge channel with the energy release system, and during energy release, according to a current load condition, indicating that the load discharge control circuit controls the voltage or current of the energy release system as required.

In an implementation, the energy conversion system comprises: a first IGBT, a second IGBT, a third IGBT and a fourth IGBT; wherein gates of the first IGBT, the second IGBT, the third IGBT and the fourth IGBT are electrically connected to a control terminal of the energy conversion control circuit separately; a collector of the first IGBT is electrically connected to a collector of the second IGBT, and serves as a positive output terminal of the energy conversion system for being electrically connected to a positive electrode of the energy storage system; an emitter of the first IGBT is electrically connected to a collector of the third IGBT, and serves as a first input connection terminal of the energy conversion system for being electrically connected to a connection terminal of the magnetic coil; an emitter of the second IGBT is electrically connected to a collector of the fourth IGBT, and serves as a second input connection terminal of the energy conversion system for being electrically connected to another connection terminal of the magnetic coil; and an emitter of the third IGBT is electrically connected to an emitter of the fourth IGBT, and serves as a negative output terminal of the energy conversion system for being electrically connected to a negative electrode of the energy storage system.

In an implementation, the energy storage system comprises a capacitor component and/or a lithium battery with a set high energy density and a set high power density.

In an implementation, the energy release system is a pure resistance discharge network, or inverts energy and returns electric energy to an external power grid, or supplies power to a component in a magnetic resonance imaging system.

In an implementation, the energy release system comprises a fifth IGBT, wherein a gate of the fifth IGBT is electrically connected to a control terminal of the load discharge control circuit, a collector of the fifth IGBT is electrically connected to a positive electrode of the energy storage system, and an emitter of the fifth IGBT is electrically connected to a negative electrode of the energy storage system.

A coil unit proposed in the aspects of the present application comprises: a magnetic coil; and the energy processing system for the magnetic coil described above.

A superconducting magnet proposed in the aspects of the present application comprises the coil unit described above.

A magnetic resonance imaging system proposed in the aspects of the present application comprises the superconducting magnet described above.

An energy processing method for a magnetic coil proposed in the aspect of the present application comprises: when demagnetization of the magnetic coil is monitored, controlling an energy conversion system to perform voltage or current regulation on electric energy of the magnetic coil, to receive the energy of the magnetic coil in a nonlinear manner by collecting the energy of the magnetic coil with a low voltage first followed by a high voltage, and to output electric energy with a stable voltage or a stable current that is adapted to an energy storage system; controlling the energy storage system to accumulate and store the electric energy output by the energy conversion system; monitoring the electric energy stored in the energy storage system, controlling an energy release system to release the electric energy stored in the energy storage system when the electric energy stored in the energy storage system reaches a set threshold or when a discharge instruction is received, and adjusting discharge power of the energy release system according to a current load condition; and
implementing nonlinear control of demagnetization speed by controlling a voltage at which the energy conversion system collects the energy of the magnetic coil and controlling the discharge power of the energy release system.

As can be seen from the above solutions, in the technical solutions in the aspects of the present application, since the energy conversion system is provided, the energy generated during the demagnetization of the magnetic coil can be converted into electric energy with the stable voltage or the stable current. Thus, the electric energy with the stable voltage or the stable current can be accumulated and stored, and the stored electricity can be released when needed. This not only reduces heat dissipation costs but also improves energy utilization.

### BRIEF DESCRIPTION OF THE DRAWINGS

Preferred aspects of the present application are described in detail below with reference to the drawings, to give those skilled in the art a clearer understanding of the above and other features and advantages of the present application. In the drawings:

FIG. 1 is an exemplary structural diagram of an energy processing system for a magnetic coil in an aspect of the present application.

FIG. 2 is an exemplary structural diagram of an energy processing system for a magnetic coil in an example of the present application.

FIG. 3 is an exemplary flowchart of an energy processing method for a magnetic coil in an aspect of the present application.

In the figures, reference numerals are as follows:

| Label | Meaning |
|---|---|
| 1 | Energy conversion system |
| 11, 12, 13, 14, 31 | IGBTs |
| 2 | Energy storage system |
| 3 | Energy release system |
| 4 | Control system |
| 41 | Main controller |
| 42 | Energy conversion control circuit |
| 43 | Charging control circuit |
| 44 | Load discharge control circuit |
| 5 | Magnetic coil |
| 301, 302, 303 | Steps |

### DETAILED DESCRIPTION

In the aspects of the present application, on the one hand, it is considered that converting the energy of a superconducting coil into heat and dissipating the heat is somewhat wasteful; and on the other hand, it is considered that the converted heat needs to be dissipated by an additionally equipped cooling system, which increases the cost. Therefore, it is considered to provide an energy storage and heat dissipation system.

To enable a clearer understanding of the objective, technical solutions and effects of the present application, specific aspects of the present application are now explained with reference to the drawings, in which identical labels indicate structurally identical components or components with similar structures but identical functions.

As used herein, “exemplary” and “schematic” mean “serving as an instance, example, or illustration.” No drawing or aspect described herein as “exemplary” or “schematic” should be interpreted as a more preferred or more advantageous technical solution.

To make the drawings appear uncluttered, only those parts relevant to the present application are shown schematically in the drawings; they do not represent the actual structure thereof as a product.

As used herein, “a” does not only mean “just this one”; it may also mean “more than one”. As used herein, “first” and “second,” etc., are merely used to differentiate between parts, not to indicate their order or degree of importance, etc.

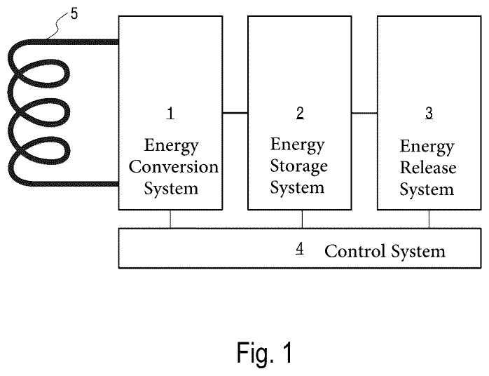

FIG. 1 is an exemplary structural diagram of an energy processing system for a magnetic coil in an aspect of the present application. As shown in FIG. 1, the energy processing system for the magnetic coil may comprise: an energy conversion system, an energy storage system 2, an energy release system 3, and a control system 4.

The energy conversion system is configured to perform voltage or current regulation on electric energy of the magnetic coil 5 during demagnetization of the magnetic coil 5, and output electric energy with a stable voltage or a stable current. In this aspect, the energy conversion system can, as needed, receive the energy of the magnetic coil 5 in a nonlinear manner by collecting the energy of the magnetic coil 5 with a low voltage first, followed by a high voltage, and convert the energy into electric energy with a stable voltage or a stable current suitable for the energy storage system 2. For example, in an implementation, at the beginning of demagnetization of the magnetic coil 5, the magnetic coil 5 is in a high current state. At this time, a lower voltage may be applied across the magnetic coil 5 to prevent the current output power of the magnetic coil 5 from being too high, thereby preventing the occurrence of quenching. In a later stage of demagnetization of the magnetic coil 5, the magnetic coil 5 is in a low current state. At this time, a higher voltage may be applied across the magnetic coil 5 so that the current output power of the magnetic coil 5 can be increased to accelerate the demagnetization speed.

The energy storage system 2 is configured to accumulate and store the electric energy output by the energy conversion system 1.

In this aspect, the energy conversion system and the energy storage system 2 can be provided to buffer the demagnetization process of the magnetic coil 5, thereby avoiding other phenomena such as quenching in the uncontrolled demagnetization process. In addition, by storing energy for the magnetic coil 5 through the energy storage system 2, system heat can also be reduced.

The energy release system 3 is configured to release electricity stored in the energy storage system 2. In this aspect, the energy release system 3 may release energy while the energy storage system 2 is storing energy, or may release energy when the amount of electricity stored in the energy storage system 2 reaches a set threshold, which can be specifically determined according to actual situations. By providing the energy release system 3, the energy in the energy storage system 2 can be released in a timely manner, so that the energy storage system 2 can smoothly store the electric energy output by the energy conversion system. The cooperation of the energy conversion system, the energy storage system 2, and the energy release system 3 can control and adjust the demagnetization process and speed, realizing nonlinear demagnetization control, and ensuring efficient energy conversion and storage.

The control system 4 is configured to control the energy conversion system to perform energy conversion on the electric energy of the magnetic coil 5 during demagnetization of the magnetic coil 5. The control system is further configured to: monitor the energy storage system 2; when the amount of energy stored in the energy storage system 2 does not reach the set threshold, control the energy storage system 2 to accumulate and store the electric energy output by the energy conversion system; when the amount of energy stored in the energy storage system 2 reaches the set threshold or when a discharge instruction is received, control the energy release system 3 to release the energy stored in the energy storage system 2. The control system is further configured to adjust the discharge power of the energy release system 4 according to a load condition. In this aspect, the demagnetization (field reduction) speed can be controlled by controlling a voltage at which the energy conversion system collects the energy of the magnetic coil (i.e., controlling the output current of the energy conversion system) and controlling the discharge power in the energy release system 3, such as the on-resistance of a transistor, so that nonlinear demagnetization (field reduction) can be implemented.

In an aspect, the control system 4 may further be configured to monitor the voltage and current of the magnetic coil 5, and determine, according to the voltage and current conditions of the magnetic coil 5, whether the magnetic coil 5 starts to be demagnetized. Alternatively, in other aspects, the control system 4 may also determine, upon receiving a demagnetization instruction from another system, that the magnetic coil 5 starts to be demagnetized.

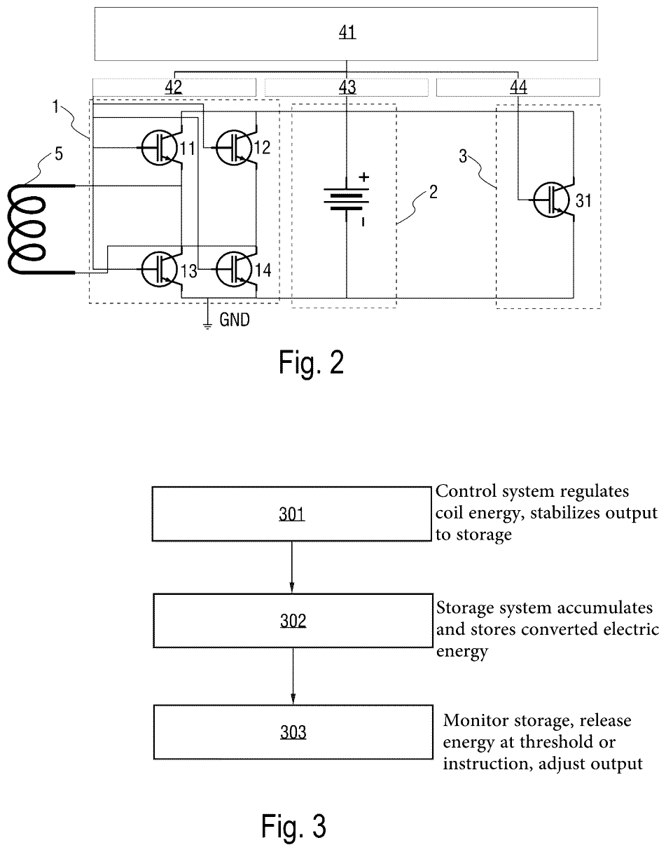

In a specific implementation, the energy processing system of the magnetic coil may be implemented in various forms. For example, FIG. 2 shows a schematic structural diagram of an energy processing system for a magnetic coil in an example of the present application.

As shown in FIG. 2, in this example, the control system 4 may comprise: a main controller 41, an energy conversion control circuit 42, a charging control circuit 43, and a load discharge control circuit 44.

The energy conversion control circuit 42 is configured to control the energy conversion system to turn on or off the electrical connection with the magnetic coil 5, and can control the energy conversion system to convert the energy of the magnetic coil 5 in a nonlinear manner by collecting the energy of the magnetic coil 5 with a low voltage first, followed by a high voltage.

The charging control circuit 43 is configured to control the energy storage system 2 to turn on or off the charging channel with the energy conversion system.

The load discharge control circuit 44 is configured to control the energy release system 3 to turn on or off the discharge channel with the energy storage system 2, and is configured to control the voltage or current of the energy release system 3.

The main controller 41 is configured to: during the demagnetization of the magnetic coil 5, send, to the energy conversion control circuit 42, a first control signal indicating that the electrical connection between the energy conversion system 1 and the magnetic coil 5 is turned on according to a required collection voltage, and simultaneously send, to the charging control circuit 43, a second control signal indicating that the charging channel between the energy storage system 2 and the energy conversion system is turned on; and when it is monitored that the amount of electricity stored in the energy storage system 2 reaches the set threshold or when the discharge instruction is received, send, to the load discharge control circuit 44, a third control signal indicating that the energy release system 3 turns on the discharge channel with the energy storage system 2, and indicating that the load discharge control circuit 44 controls the voltage or current of the energy release system 3 as required. For example, according to a current load condition, the load discharge control circuit 44 may be instructed to control the voltage or current of the energy release system 3 as required.

In an aspect, the main controller 41 may further be configured to monitor the voltage and current of the magnetic coil 5 and determine, according to the voltage and current conditions of the magnetic coil 5, whether the magnetic coil 5 starts to be demagnetized. Alternatively, in other aspects, the main controller 41 may also determine, upon receiving a demagnetization instruction from another system, that the magnetic coil 5 starts to be demagnetized.

In an example shown in FIG. 2, the energy conversion system includes 4 IGBTs, namely, a first IGBT 11, a second IGBT 12, a third IGBT 13, and a fourth IGBT 14.

The gates of the four IGBTs are electrically connected to a control terminal of the energy conversion control circuit 42 separately.

The collector of the first IGBT 11 is electrically connected to the collector of the second IGBT 12, and serves as a positive output terminal of the energy conversion system 1 for being electrically connected to a positive electrode of the energy storage system 2.

The emitter of the first IGBT 11 is electrically connected to the collector of the third IGBT 13, and serves as a first input connection terminal of the energy conversion system for being electrically connected to a connection terminal of the magnetic coil 5.

The emitter of the second IGBT 12 is electrically connected to the collector of the fourth IGBT 14, and serves as a second input connection terminal of the energy conversion system 1 for being electrically connected to another connection terminal of the magnetic coil 5.

The emitter of the third IGBT 13 is electrically connected to the emitter of the fourth IGBT, and serves as a negative output terminal of the energy conversion system for being electrically connected to a negative electrode of the energy storage system 2.

In this example, the four IGBTs are turned on and off under the control of the energy conversion control circuit 42, and when turned on, they convert the energy of the magnetic coil 5 into a stable voltage or current and supply it to the energy storage system 2.

In this example, the energy storage system 2 may comprise a component capable of storing energy, such as a capacitor component and/or a lithium battery. FIG. 2 shows only a rechargeable battery component. In other examples, a capacitor component may also be used in place of the rechargeable battery component, or a capacitor component in parallel with the rechargeable battery component may further be provided on the basis of FIG. 2.

The energy storage system 2 in this aspect meets the set high energy density and high power density. Table 1 below shows the type of the energy storage system 2 used in an example and the value ranges of its energy density and power density.

TABLE 1

| Type of energy | Energy density range | Power density range |
|---|---|---|
| storage system | (Wh/kg) | (W/kg) |
| Lithium-ion battery | 150-250 | 150-250 |
| Lithium polymer battery | 200-300 | 600-900 |
| Super capacitor | 30-50 | 300-40 000 |

In this example, the energy release system 3 may be a pure resistive discharge network, or may invert energy and return it to an external power grid, or may supply power to a component in the magnetic resonance imaging system, such as a mini UPS. In a specific implementation, it may be determined according to actual situations, which is not limited here. For example, in the example shown in FIG. 2, the energy release system 3 comprises a fifth IGBT 31. The gate of the fifth IGBT 31 is electrically connected to a control terminal of the load discharge control circuit 44, the collector of the fifth IGBT is electrically connected to a positive electrode of the energy storage system 2, and the emitter of the fifth IGBT is electrically connected to a negative electrode of the energy storage system 2. The fifth IGBT 31 can release electric energy of a set voltage or current under the control of the load discharge control circuit 44. For example, the voltage or current of the fifth IGBT 31 may be controlled by controlling the on-resistance of the fifth IGBT 31.

When the energy release system 3 is a pure resistance discharge network, a heat sink may be provided for the pure resistance discharge network to dissipate the heat of the pure resistance discharge network.

The aspects of the present application further provide a coil unit, comprising: a magnetic coil 5 and the energy processing system for the magnetic coil as described in any of the above aspects.

The aspects of the present application further provide a superconducting magnet comprising the coil unit described above.

The aspects of the present application further provide a magnetic resonance imaging system, comprising the superconducting magnet described above.

In addition, the aspects of the present application further provide an energy processing method for a magnetic coil, which is used to implement the energy processing system for the magnetic coil shown in FIG. 1 or 2. For example, FIG. 3 shows an exemplary flowchart of an energy processing method for a magnetic coil in an aspect of the present application. For details not described in detail in the method, reference may be made to the corresponding description of the energy processing system for the magnetic coil described above, and they will not be repeated here. As shown in FIG. 3, the method may comprise the following processing:

Step 301: When demagnetization of the magnetic coil 5 is monitored, control an energy conversion system to perform voltage or current regulation on electric energy of the magnetic coil 5, receive the energy of the magnetic coil in a nonlinear manner by collecting the energy of the magnetic coil with a low voltage first followed by a high voltage, and output electric energy with a stable voltage or a stable current that is adapted to an energy storage system.

In the example shown in FIG. 2, the four IGBTs may be controlled to be turned on during the demagnetization of the magnetic coil 5.

Step 302: Control the energy storage system 2 to accumulate and store the electric energy output by the energy conversion system 1.

In the example shown in FIG. 2, the positive and negative connection terminals of the energy storage system 2 may be controlled to turn on the charging channel with the energy conversion system 1.

Step 303: Monitor the electric energy stored in the energy storage system 2, control an energy release system 3 to release the electric energy stored in the energy storage system 2 when the electric energy stored in the energy storage system 2 reaches a set threshold or when a discharge instruction is received, and simultaneously adjust the discharge power of the energy release system 3 according to a current load condition.

In this aspect, the nonlinear control of demagnetization speed is implemented by controlling a voltage at which the energy conversion system collects the energy of the magnetic coil and controlling the discharge power of the energy release system.

In the example shown in FIG. 2, when the amount of electricity stored in energy storage system 2 reaches a set threshold or when a discharge instruction is received, positive and negative connection terminals of energy storage system 2 are controlled to turn on a discharge channel with energy release system 3. Also, the discharge voltage of the fifth IGBT is adjusted according to a current load condition. This implementation in this example can realize a controllable discharge rate, and thus, the demagnetization speed of the superconducting magnet can be freely controlled.

It should be understood that “and/or” used herein is intended to include any and all possible combinations of one or more of associated listed items.

The number of aspects of the present application is only used for description and does not represent the advantages of the aspects.

The technical solutions in the aspects of this application have the following beneficial effects:
(1) Improved efficiency: The use of the energy conversion system ensures more efficient energy conversion from a superconducting coil to an energy storage system such as a lithium battery and/or a super capacitor. This increase in efficiency reduces energy losses during the energy conversion process, maximizes the overall system efficiency, and minimizes heat output.
(2) Reduced size and weight: Compared with the bulky RDL, the aspects of the present application provide a compact and lightweight energy release system. Moreover, the energy storage system has high energy density, and the energy conversion system has high efficiency and low heat output. Therefore, the size and weight of the heat sink can be greatly reduced or even eliminated, which makes it more convenient to integrate the heat sink into MRI equipment.
(3) Cost saving: Integrating an energy storage component, such as a lithium battery or a super capacitor, into the energy storage system can eliminate the need for the RDL system, thereby saving a lot of costs. In addition, the energy storage component such as the lithium battery provides a cost-effective solution for energy dissipation in the superconducting coil, reducing manufacturing and maintenance costs. Furthermore, energy storage equipment such as the lithium battery is also cost-effective in terms of manufacturing, maintenance and overall operating expenses due to its efficient use and reduced power losses through the energy conversion system.
(4) Enhanced energy density and power density: The energy storage system uses the lithium battery and/or the super capacitor as an energy storage component, as shown in Table above. It has a very high energy density, which enables it to store a large amount of energy in a compact form. The reduction in size and weight is directly attributed to the excellent energy density provided by the lithium battery, etc. The addition of the super capacitor greatly improves the power density, enabling its peak energy storage current to reach thousands of amperes. In addition, the removal of bulky components commonly found in RDL systems further facilitates the reduction in overall size and weight. (5) Fast demagnetization and minimum heat output: Conventional RDL systems dissipate energy as heat and require additional heat sinks. The energy processing system in this aspect has an efficient energy conversion system and an energy storage system with high energy density and power density, so that fast demagnetization can be realized without exceeding the maximum demagnetization (field reduction) speed. Currently available fast charging batteries can achieve a charging speed of up to 2 C to 4 C, going from 0% to 80%, in just fifteen minutes. Combined with a super capacitor, it can withstand a charging current of thousands of amperes in the early stages. The control system 4 adjusts the charging level of the battery before each demagnetization operation to ensure that sufficient energy is available for the next demagnetization process. If the electricity of the battery becomes low during the field reduction period, the control system will control the energy release system to gradually release the field reduction energy. In the case of energy depletion in the energy storage system, the control system can adjust the energy input to charge the battery, and the excess energy is released through the energy release system. Using a 3 KWh battery can maintain a maximum peak field reduction power of up to 2 KW, and only a 6 KWh battery is sufficient to support two consecutive field reductions. However, this situation is extremely unlikely to occur. After the field reduction is completed, it takes several hours for a 3 T magnet to raise the field, which gives the battery enough time to release energy through the energy release system in preparation for the next consecutive field rise.
(5) Alleviating deceleration and rapid cooling: When the infrastructure fails, a deceleration load may work. The magnetic coil will be heated to a quenching temperature within a few hours. Before reaching the quenching temperature, the magnet should be gradually reduced to a zero magnetic field. The traditional field reduction speed is linear. Regardless of whether the magnetic coil is in a high current state or a low current state, the field is reduced at a stable speed, which causes the magnetic coil to quench at a high current. The ideal state should be that: when the magnetic coil is in a high current, a low-speed field reduction can be used, because the low speed can mitigate quenching during the field reduction. When the magnetic coil is in a low current, the field reduction speed can be very fast because the magnetic coil has a large margin. In the aspects of the present disclosure, by controlling the output current of the energy conversion system and controlling the discharge power in the energy release system 3 such as the on-resistance of the transistor, the demagnetization (field reduction) speed can be controlled to start slow and then accelerate, so that a nonlinear field reduction speed can be provided, and the total deceleration duration can also be shortened. It can be seen that the solution in this aspect can smooth and control the field reduction speed of each stage and can smooth the heat generation power during the field reduction process.

The foregoing descriptions are only preferred aspects of the present application and are not intended to limit the present application. Any modifications, equivalent replacements, and improvements made without departing from the spirit and principle of the present application shall fall within the scope of protection of the present application.

1. An energy processing system for a magnetic coil, comprising:
an energy conversion system configured to: perform voltage or current regulation on electric energy of the magnetic coil during demagnetization of the magnetic coil, receive the energy of the magnetic coil in a nonlinear manner by collecting the energy of the magnetic coil with a low voltage first followed by a high voltage, and output electric energy with a stable voltage or a stable current that is adapted to an energy storage system,
wherein the energy storage system is configured to accumulate and store the electric energy output by the energy conversion system;
an energy release system configured to release electricity stored in the energy storage system; and
a control system configured to:
control the energy conversion system to perform energy conversion during the demagnetization of the magnetic coil;
monitor the energy storage system, and when an amount of electricity stored in the energy storage system does not reach a set threshold, control the energy storage system to accumulate and store the electric energy output by the energy conversion system, and when the amount of electricity stored in the energy storage system reaches the set threshold or when a discharge instruction is received, control the energy release system to release the electricity stored in the energy storage system; and
adjust discharge power of the energy release system,
wherein nonlinear control of demagnetization speed is implemented by controlling a voltage at which the energy conversion system collects the energy of the magnetic coil and controlling the discharge power of the energy release system.

2. The energy processing system for the magnetic coil according to claim 1, wherein the control system comprises:
an energy conversion control circuit configured to control the energy conversion system to turn on or off an electrical connection with the magnetic coil, and being able to control the energy conversion system to convert the energy of the magnetic coil in a nonlinear manner by collecting the energy of the magnetic coil with a low voltage first followed by a high voltage;
a charging control circuit configured to control the energy storage system to turn on or off a charging channel with the energy conversion system;
a load discharge control circuit configured to control the energy release system to turn on or off a discharge channel with the energy storage system, and configured to control a voltage or current of the energy release system; and
a main controller configured to: during the demagnetization of the magnetic coil, send, to the energy conversion control circuit, a first control signal indicating that an electrical connection between the energy conversion system and the magnetic coil is turned on according to a required collection voltage, and simultaneously send, to the charging control circuit, a second control signal indicating that the charging channel between the energy storage system and the energy conversion system is turned on; and when it is monitored that the amount of electricity stored in the energy storage system reaches the set threshold or when the discharge instruction is received, send, to the load discharge control circuit, a third control signal, indicating that the energy release system turns on the discharge channel with the energy storage system, and indicating that the load discharge control circuit controls the voltage or current of the energy release system as required.

3. The energy processing system for the magnetic coil according to claim 2, wherein the energy conversion system comprises:
a first IGBT;
a second IGBT;
a third IGBT; and
a fourth IGBT,
wherein:
gates of the first IGBT, the second IGBT, the third IGBT, and the fourth IGBT are electrically connected to a control terminal of the energy conversion control circuit separately;
a collector of the first IGBT is electrically connected to a collector of the second IGBT, and serves as a positive output terminal of the energy conversion system for being electrically connected to a positive electrode of the energy storage system;
an emitter of the first IGBT is electrically connected to a collector of the third IGBT, and serves as a first input connection terminal of the energy conversion system for being electrically connected to a connection terminal of the magnetic coil;
an emitter of the second IGBT is electrically connected to a collector of the fourth IGBT, and serves as a second input connection terminal of the energy conversion system for being electrically connected to another connection terminal of the magnetic coil; and
an emitter of the third IGBT is electrically connected to an emitter of the fourth IGBT, and serves as a negative output terminal of the energy conversion system for being electrically connected to a negative electrode of the energy storage system.

4. The energy processing system of the magnetic coil according to claim 1, wherein the energy storage system comprises a capacitor component and/or a lithium battery with a set high energy density and a set high power density.

5. The energy processing system of the magnetic coil according to claim 2, wherein the energy release system is a pure resistance discharge network, or inverts energy and returns electric energy to an external power grid, or supplies power to a component in a magnetic resonance imaging system.

6. The energy processing system for the magnetic coil according to claim 5, wherein the energy release system comprises a fifth IGBT, a gate of the fifth IGBT is electrically connected to a control terminal of the load discharge control circuit, a collector of the fifth IGBT is electrically connected to a positive electrode of the energy storage system, and an emitter of the fifth IGBT is electrically connected to a negative electrode of the energy storage system.

7. A coil unit, comprising:
a magnetic coil; and
the energy processing system for the magnetic coil according to claim 1.

8. A superconducting magnet, comprising the coil unit according to claim 7.

9. A magnetic resonance imaging system, comprising the superconducting magnet according to claim 8.

10. An energy processing method for a magnetic coil, comprising:
when demagnetization of the magnetic coil is monitored, controlling an energy conversion system to perform voltage or current regulation on electric energy of the magnetic coil, to receive the energy of the magnetic coil in a nonlinear manner by collecting the energy of the magnetic coil with a low voltage first followed by a high voltage, and to output electric energy with a stable voltage or a stable current that is adapted to an energy storage system;
controlling the energy storage system to accumulate and store the electric energy output by the energy conversion system;
monitoring the electric energy stored in the energy storage system;
controlling an energy release system to release the electric energy stored in the energy storage system when the electric energy stored in the energy storage system reaches a set threshold or when a discharge instruction is received, and adjusting discharge power of the energy release system according to a current load condition; and
implementing nonlinear control of demagnetization speed by controlling a voltage at which the energy conversion system collects the energy of the magnetic coil and controlling the discharge power of the energy release system.
